(19) United States
(12) Patent Application Publication
(10) Pub. No.: US 2009/0034827 A1
(43) Pub. Date: Feb. 5, 2009

(54) Inspection device, inspection method, method of manufacturing color filter, and computer-readable storage medium containing inspection device control program

(75) Inventor: Tamon Iden, Nara (JP)

Correspondence Address: EDWARDS ANGELL PALMER & DODGE LLP, P.O. BOX 55874, BOSTON, MA, 02205, US

(73) Assignee: Sharp Kabushiki Kaisha, Osaka (JP)

(21) Appl. No.: 12/220,850

(22) Filed: Jul. 29, 2008

(30) Foreign Application Priority Data
Jul. 31, 2007 (JP) 199979/2007

(51) Int. Cl. G06K 9/00; G03F 1/00

(52) U.S. Cl. 382/141; 430/7

(57) ABSTRACT

An inspection device of the present invention includes: a linear irregularity detecting section for detecting linear irregularities individually in an image L of dots on a substrate being inspected by projecting light from a first direction and in an image R of the dots by projecting light from a second direction, which differs from the first direction; a specific-cycle irregularity extracting section for extracting linear irregularities detected at predetermined intervals T in the individual mages L and R, the intervals being taken vertical to the linear irregularities on the substrate; and a detection-target-irregularity extracting section for extracting a linear irregularity detected in both the images L and R as a detection-target linear irregularity. The device therefore is capable of detecting only linear irregularities of a specific cycle which are caused by the presence of dots having irregular thickness when compared to a dot with normal thickness.

This nonprovisional application claims priority under 35 U.S.C. §119(a) on Patent Application No. 2007-199979 filed in Japan on Jul. 31, 2007, the entire contents of which are hereby incorporated by reference.

### FIELD OF THE INVENTION

The present invention relates to, among others, inspection devices that detect linear irregularities which develop at a specific cycle (or at a specific period) on an inspection object having surface mounds, by inspecting images captured of the peripheries of the surface mounds.

### BACKGROUND OF THE INVENTION

Liquid crystal displays have become bigger in size over recent years, and demand for such displays is ever growing. However, price needs to be cut to see more widespread use of liquid crystal displays. There is an increasing demand to cut down the cost of, especially, the color filter, which is a relatively expensive component in the liquid crystal display.

A recent notable trend is use of inkjet technology in the fabrication of color filters. In the technology, a color filter is formed by ejecting R (red), G (green), and B (blue) ink to make dots (three of which make up a pixel) from nozzles of an inkjet head. The inkjet technology requires fewer steps and produces little waste ink. These advantages contribute to shorter processes and cost cuttings.

The use of inkjet technology in color filter fabrication however has a disadvantage: linear irregularities could develop at a specific cycle due to a cause in the manufacturing process of the color filter. The linear irregularities occur from deviations in thickness of the color filter. They are visible (by light transmitting through the color filter) and could seriously affect the quality of the liquid crystal display.

Here is why linear irregularities develop at a specific cycle on a color filter formed by inkjet technology. To fabricate a color filter by inkjet technology, a head unit equipped with a plurality of ink-ejecting nozzles is moved in a scan direction (plotting direction) over a transparent substrate on which a black matrix has been formed. While the head is being moved that way, liquid substances are ejected from the nozzles onto predetermined areas each surrounded by the black matrix on the transparent substrate. Upon completion of the ejection in the scan direction, the head unit is moved a predetermined distance in a direction perpendicular to the scan direction. The head unit is then moved again in the scan direction and sequentially ejects liquid substances. This operation is repeated to form dots separated by the black matrix on the transparent substrate, that is, a color filter.

Linear irregularities can develop on the color filter at nozzle intervals if, for example, the quantity of liquid substance ejected varies from one nozzle of the head unit to the other for some reason in the fabrication process. The linear irregularities can develop on the color filter at head unit intervals if, for example, a nozzle is clogged for some reason. These are a few examples of linear irregularities that could develop at various cycles depending on their causes in the fabrication of a color filter by inkjet technology.

Color filters with linear irregularities are of poor quality as mentioned earlier and need to be detected in the manufacturing stage to reject them. Trouble is that the linear irregularities on a color filter develop due to deviations in thickness of the color filter on the order of 10 to 100 nm: it is difficult to detect the linear irregularities by a thickness measuring method that exploits light interference or transmitted light.

A conventional method, addressing this problem, is to measure the angle of the peripheral face of the dot on the color filter. The method enables indirect measurement of the thickness, hence detection of the linear irregularities. The method will now be described in reference to (a) to (c) of FIG. 8 which illustrate a thickness measuring method by means of measurement of the angle of the peripheral face of the dot.

(a) of FIG. 8 depicts the angle of the peripheral face of the dot when the thickness is normal. In other words, it is assumed here that the angle is equal to α on both sides when the thickness is normal (=h).

Meanwhile, (b) of FIG. 8 depicts the angle of the peripheral face of the dot when the thickness is too small. The angle is β on both sides. A comparison of (a) and (b) of FIG. 8 would show that β<α it could therefore be seen that the thickness h′ in (b) of FIG. 8 is smaller than the normal thickness h in (a) of FIG. 8.

When a measurement of the angle of the peripheral face of the dot shows that the angle is smaller than the normal value α as above, it would be safely concluded that the thickness of the dot is smaller than the normal thickness h. Accordingly, the linear irregularities which appear on the order of 10 to 100 nm can be detected.

Some linear irregularities are not caused by a uniform deviation in thickness around the entire peripheral face of the dot as shown in (b) of FIG. 8. A dot formed by inkjet technology on the color filter may deform non-uniformly as illustrated in (c) of FIG. 8. The linear irregularities resulting from non-uniform deformation of fabricated dots will be referred to as non-uniform deformation irregularities in the following description.

The non-uniform deformation irregularities may be erroneously recognized as deviations in thickness of dots by the aforementioned conventional inspection based on images captured of the peripheral face of the dot because the peripheral face of the dot shows different tilt angles from normal. As shown in (c) of FIG. 8, when the dot leans in a direction, the angle of the peripheral face of the dot differs on two sides of a dot.

For example, in (c) of FIG. 8, the angle of the peripheral face of the dot on the left-hand side (=β) is smaller than the normal angle α. The dot in (c) of FIG. 8 is therefore regarded by the conventional inspection method as having an improper thickness, thus as being defective. Nevertheless, referring again to (c) of FIG. 8, the angle of the peripheral face of the dot on the right-hand side (=γ) is greater than the normal angle α. As a result, the dot in (c) of FIG. 8 has a normal thickness value.

No deviation in thickness actually occurs with the non-uniform deformation irregularities as described above. Hence, no linear irregularities are visible in the light transmitting through a color filter having the non-uniform deformation irregularities. A color filter with non-uniform deformation irregularities has no problems as a commercial product and should be regarded as acceptable. In practice, these color filters with non-uniform deformation irregularities, which should be regarded as being acceptable, are determined to be defective by the conventional inspection in which the peripheral face of the dot is measured to measure a deviation in thickness indirectly if the non-uniform deformation irregularities occur at random positions across a broad bandwidth (spatial frequencies).

The discussion so far shows that it is important in the inspection for detection of linear irregularities to distinguish the linear irregularities that should be regarded as being acceptable (non-uniform deformation irregularities) from the linear irregularities, occurring from deviations in thickness from a normal color filter at a specific cycle which are attributable to a process, that should be regarded as being defective.

Conventional art of linear irregularity detection is described in patent documents 1 to 3 below to name a few. According to patent document 1, luminance data is added up separately for the vertical and the horizontal direction in an image captured of an inspection object in order to generate integral data. Moving averages are calculated from the integral data to calculate integral moving average data. Linear irregularities are detected by taking differentials between the integral data and the integral moving average data. The technology, being robust to noise, can single out linear irregularities at high precision.

Patent document 2 employs Fourier transform in a method of measuring the surface geometry of an object which exploits interference of light. A portion of the surface of the object in which geometry is measured is specified on the basis of a point at which spectrum has a maximum amplitude in a frequency coordinate system and a point, located between that point and the origin, at which spectrum has a minimum amplitude. The technology eliminates the need for an operator to manually specify a portion of the surface of the object in which geometry is measured.

In patent document 3, an image captured of a color filter is subjected to a binarization process. AND operation is then implemented for both ends of the dot on the color filter to detect defects. The technology can detect minuscule foreign objects adhering to the dot on the color filter.

The technology of patent document 1 is not suitable for detection of linear irregularities which occur at predetermined specific cycles because a portion of two-dimensional data is set aside to generate the integral data. In addition, patent document 1 gives no consideration to non-uniform deformation irregularities. The non-uniform deformation irregularities (defects that are safely regarded as being acceptable) may be erroneously identified as defects.

The technology of patent document 2 is not suitable for evaluation in relation to predetermined specific cycles because the surface geometry of an object is analyzed using the point at which spectrum has a maximum value. Patent document 2, similarly to patent document 1, gives no consideration to non-uniform deformation irregularities and may suffer from the non-uniform deformation irregularities.

It is difficult to binarize linear irregularities for detection because there is only small difference in luminance between sites where linear irregularities have occurred and sites where no linear irregularities have occurred. The technology of patent document 3 is therefore not suitable for detection of linear irregularities. Patent document 3, again, gives no consideration to non-uniform deformation irregularities. The non-uniform deformation irregularities may be erroneously detected.

It is of extreme importance to, in a color filter inspection step, distinguish defects which can be safely regarded as being acceptable from those which cannot and detect linear irregularities which develop at a specific cycle, in order to determine causes of abnormalities in a manufacturing process.

Patent Document 1: Japanese Unexamined Patent Publication (Tokukai) No. 2005-77181 (published Mar. 24, 2005)

Patent Document 2: Japanese Unexamined Patent Publication (Tokukai) No. 2002-286407 (published Oct. 3, 2002)

Patent Document 3: Japanese Unexamined Patent Publication No. 7-20065/1995 (Tokukaihei 7-20065; published Jan. 24, 1995)

### SUMMARY OF THE INVENTION

The present invention, conceived in view of the problems, has an objective of detecting only linear irregularities, occurring from deviations in thickness in view of normal thickness at a specific cycle (or at a specific period) due to a cause in the manufacturing process, which should be regarded as being defective, and not detecting defects which are safely regarded as being acceptable (non-uniform deformation irregularities).

An inspection device of the present invention is, to address the problems, characterized in that the device detects linear irregularities occurring on an inspection object having a plurality of surface mounds on an inspection surface and also in that the device includes: linear irregularity detecting means for detecting linear irregularities individually in a first and a second image, the first image being produced of the surface mounds by projecting light from a first direction onto the inspection surface, the second image being produced of the surface mounds by projecting light from a second direction, which differs from the first direction, onto the inspection surface; specific-cycle irregularity extracting means for extracting linear irregularities detected at predetermined intervals in the individual first and second images, the intervals being taken vertical to the linear irregularities on the inspection surface; and detection-target-irregularity extracting means for extracting a linear irregularity detected in both the first and second images as a detection-target linear irregularity.

According to the arrangement, the reflections of the light projected from two different directions (first the second directions) are caught as the first and second images. Linear irregularities are detected in the first and second images. The detection could find non-cyclic linear irregularities, non-uniform deformation irregularities, and other various linear irregularities. In this context, linear regions in which the surface mounds on the inspection object have either a small or large thickness-direction dimension outside a predetermined range are termed linear irregularities.

Accordingly, the device extracts the linear irregularities detected at predetermined intervals taken vertical to the linear irregularities on the inspection surface, that is, the linear irregularities occurring at a specific cycle. The arrangement can hence extract only the linear irregularities occurring at a specific cycle due to a cause in the manufacturing process, excluding non-cyclic linear irregularities from the linear irregularities that have been detected.

Under these circumstances, if linear irregularities occur due to a less-than-normal thickness of the surface mounds on the inspection object, the linear irregularities are detectable from no matter which direction light is projected. In contrast, if non-uniform deformation irregularities occur, the linear irregularities may not be detected depending on the direction of projected light.

From the extracted linear irregularities occurring at a specific cycle, the arrangement further extracts those detected in both the first and second images, that is, the linear irregularities detected at the same positions in the two images. In other words, the arrangement extracts only the linear irregularities which occur due to a less-than-normal or more-than-normal thickness of the surface mounds.

Thus, the device is capable of detecting, selectively from non-cyclic linear irregularities, non-uniform deformation irregularities, and other various linear irregularities, only the linear irregularities occurring from a less-than-normal thickness of the surface mounds on the inspection object and having a specific cycle due to a cause in the manufacturing process of the inspection object.

Additional objects, advantages and novel features of the invention will be set forth in part in the description which follows, and in part will become apparent to those skilled in the art upon examination of the following or may be learned by practice of the invention.

### BRIEF DESCRIPTION OF THE DRAWINGS

FIG. 1 is a block diagram of an embodiment of the present invention, or a schematic of an inspection system in accordance with the present invention.

FIG. 2 is an illustration of a method, implemented on the inspection system, whereby imaging devices and illumination devices capture an image of a substrate for inspection.

FIG. 3 is a flow chart illustrating an exemplary process executed by the inspection system.

FIG. 4 is an illustration of a concrete example of the process shown in the flow chart.

FIG. 5 is an illustration of an exemplary data flow in another inspection system.

FIG. 6 is an illustration of another exemplary data flow in the inspection system.

FIG. 7(a) is an illustration of linear irregularities being detected, as an example, in a plurality of regions.

FIG. 7(b) is an illustration of an exemplary relationship between a coordinate taken on a substrate being inspected and average defectiveness values.

FIG. 7(c) is an illustration of an exemplary relationship between a coordinate taken on a substrate being inspected and a detection count indicating the number of regions in which a linear irregularity is detected.

FIG. 8 illuminates a thickness measuring method which involves measurement of the angle of the peripheral face of the dot. (a) of FIG. 8 depicts the angle of the peripheral face of the dot when the thickness is normal. (b) of FIG. 8 depicts the angle of the peripheral face of the dot when the thickness is too thin. (c) of FIG. 8 depicts the angle of the peripheral face of the dot when the dot fabricated on a color filter has deformed non-uniformly.

### DESCRIPTION OF THE EMBODIMENTS

### Embodiment 1

### Inspection System Structure

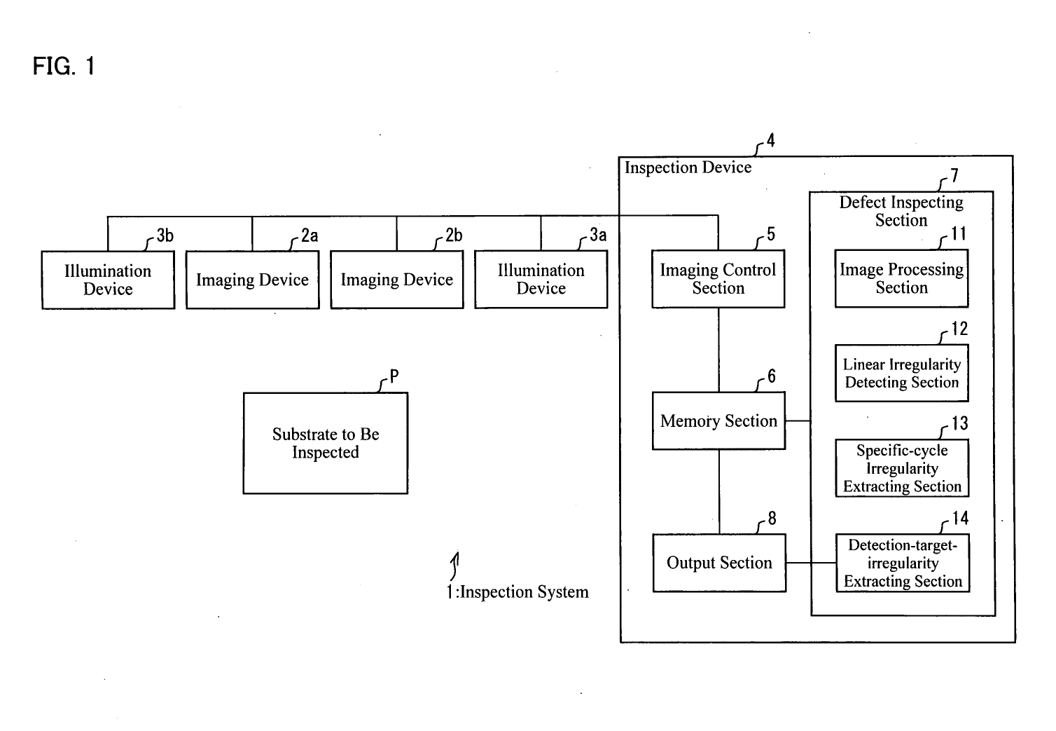

The following will describe an embodiment of the present invention in reference to FIGS. 1 to 7. First, an inspection system 1 of the present embodiment will be schematically described in reference to FIG. 1. FIG. 1 is a schematic block diagram of the inspection system 1. As illustrated, the inspection system 1 inspects a substrate P and is composed primarily of an imaging device 2a, an imaging device 2b, an illumination device 3a, an illumination device 3b, and an inspection device 4.

Here, the substrate P to be inspected by the inspection system 1 is assumed to be a color filter substrate. A “color filter,” throughout the following description, refers to a filter enabling a color display on a display device by transmitting particular wavelengths of light. The color filter is assumed to be formed by ejecting liquid substances by inkjet technology onto a glass substrate on which a black matrix has been formed. In this context, a glass substrate on which a black matrix and a color filter have been formed is termed a color filter substrate.

The substrate P to be inspected is fixed to a frame (not shown) so that the surface colored by inkjet technology are visible to the imaging devices 2a and 2b. The object to be inspected is not limited to a color filter substrate. The object may be anything that has regularly arranged surface mounds and develops linear irregularities due to mound-to-mound deviations in thickness.

The imaging devices 2a and 2b capture an image of the substrate P. The illumination devices 3a and 3b project light onto the substrate P. Specifically, the imaging device 2a captures the reflection of the light projected onto the substrate P by the illumination device 3a, and the imaging device 2b captures the reflection of the light projected onto the substrate P by the illumination device 3b.

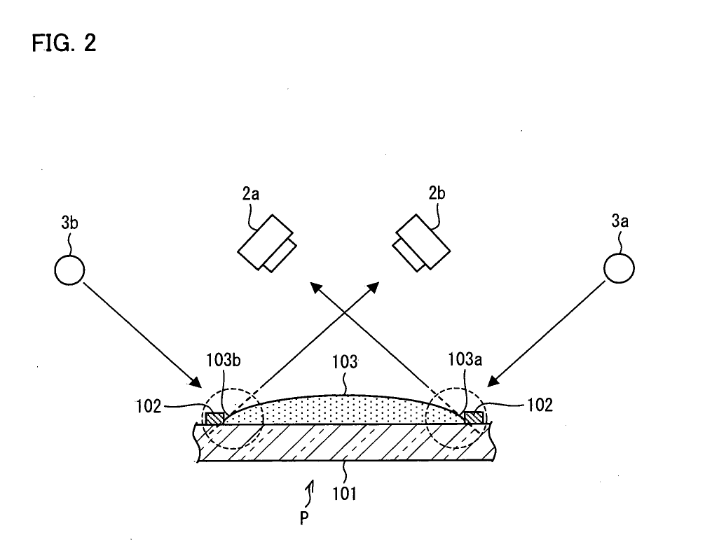

In other words, in the inspection system 1, light is projected to the periphery of a dot on the substrate P. The reflection of the light is captured to produce an image. A tilt angle on the peripheral face of the dot is obtained from the image to detect deviations in thickness of each dot. This methodology will be described in reference to FIG. 2.

FIG. 2 is an illustration of a method whereby the imaging devices 2a and 2b and the illumination devices 3a and 3b capture an image of the substrate P being inspected. A black matrix 102 is formed on a transparent substrate 101 as shown in the figure. Dots 103 are formed by inkjet technology in areas surrounded by the black matrix 102, to complete the fabrication of the substrate P. Each dot 103 contacts the black matrix 102 at peripheral faces 103a and 103b of that dot.

The imaging devices 2a and 2b produce an image of the peripheral faces 103a and 103b. Specifically, the peripheral face 103a on the right is illuminated by the illumination device 3a at a predetermined angle to the substrate P from outside the dot 103. The reflection of that light is captured by the imaging device 2a fixed at a predetermined angle to the substrate P to produce an image. Similarly, the peripheral face 103b on the left is illuminated by the illumination device 3b at a predetermined angle to the substrate P from an opposite direction to the illumination device 3a as viewed from the substrate P. The reflection of that light is captured by the imaging device 2b to produce an image.

Note that FIG. 2 only shows the capturing of reflection from the peripheral faces 103a and 103b of a single dot 103 for the sake of simplicity. In actuality, the transparent substrate 101 has thereon a matrix of numerous dots. Reflection occurs at the peripheral face of each of the dots similarly to the peripheral faces 103a and 103b. Reflection from these peripheral faces is captured by the imaging devices 2a and 2b to produce images.

Throughout the description below, the image data obtained from an image produced by the imaging device 2a capturing reflection from the peripheral face 103a will be referred to as the image R, and the image data obtained from an image produced by the imaging device 2b capturing reflection from the peripheral face 103b will be referred to as the image L. The imaging devices 2a and 2b are connected to the inspection device 4 by wire or wirelessly. The images L and R are transmitted to the inspection device 4.

The inspection device 4 inspects the images L and R produced by the imaging devices 2a and 2b capturing reflection from the peripheral faces 103a and 103b to see whether or not the substrate P has developed linear irregularities. The inspection device 4, as shown in the figure, includes an imaging control section 5, a memory section 6, a defect inspecting section 7, and an output section 8.

The imaging control section 5 controls the operation of the imaging devices 2a and 2b and the illumination devices 3a and 3b to produce images of the substrate P and feed the inspection device 4 with the produced images L and R. The imaging control section 5 records the images L and R in the memory section 6 in association with data identifying the substrate P. The configuration enables production of multiple substrates P and inspection of the substrates P for linear irregularities.

Apart from the images L and R fed to the imaging control section 5 described above, the memory section 6 also stores data that is to be used by the defect inspecting section 7 in detecting defects, data that indicates results of the detecting of defects, as well as other kinds of data.

The defect inspecting section 7 analyzes the images L and R to detect linear irregularities on the substrate P. Specifically, the defect inspecting section 7 includes an image processing section (frequency domain data generating means) 11, a linear irregularity detecting section (linear irregularity detecting means) 12, a specific-cycle irregularity extracting section (specific-cycle irregularity extracting means) 13, and an inspection object irregularity extracting section. The individual sections perform respective predetermined operations to detect linear irregularities.

The image processing section 11 performs projection processing, noise elimination, and other kinds of image processing on the images L and R. By virtue of the image processing, linear irregularities can be readily and accurately detected from the images L and R. The defect inspecting section 7 can still detect linear irregularities without the image processing section 11. It is preferred however that the image processing section 11 includes the image processing section 11 to increase precision in detecting linear irregularities.

The linear irregularity detecting section 12 analyzes the images L and R processed by the image processing section 11. The section 12 detects the positions of linear irregularities on both of the images L and R and also detects defectiveness for each of the detected linear irregularities. Defectiveness indicates how much the thickness of a dot deviates from a normal value. The greater the defectiveness, the thinner or thicker the dot is than normal dots.

Now, a method will be described whereby the linear irregularity detecting section 12 detects linear irregularities. The illumination devices 3a and 3b projects light which is then reflected by the substrate P. The reflections are relatively strong if the dot is thicker than other dots and relatively weak if the dot is thinner than other dots. The deviations of the intensity of the reflections show up as irregularities in the images L and R of the substrate P being inspected.

Generally, deviations in thickness in inkjet technology often occur along a line parallel to the scan direction (plotting direction) of the head unit as described earlier in the Background Art section. As a result, irregularities which develop due to a cause in the manufacturing process are detected as a line extending in the plotting direction (“linear irregularities”).

The reflection intensity deviations appear deviations in luminance in the images L and R. The linear irregularity detecting section 12 can therefore determine positions, directions, defectiveness values, etc. for the linear irregularities from the distribution of luminance in the images L and R. For example, the linear irregularity detecting section 12 can detect, as linear irregularities, regions where luminance is either below or above a predetermined threshold level in the images L and R. The section 12 can also calculate, as a defectiveness value, a difference between the luminance level of a region containing no linear irregularities and the luminance level of a region containing linear irregularities.

The specific-cycle irregularity extracting section 13 extracts the linear irregularities occurring at a specific cycle (specific period) T from the linear irregularities detected by the linear irregularity detecting section 12. Specifically, the specific-cycle irregularity extracting section 13 does so by checking each linear irregularity detected by the linear irregularity detecting section 12 to see if there is another linear irregularity at a distance T from that linear irregularity. Linear irregularities occurring at specific cycles are, as mentioned earlier, generally detected as lines of irregularities parallel a plotting direction; the specific-cycle irregularity extracting section 13 determines intervals, between the linear irregularities, perpendicular to the plotting direction in the images L and R.

Apart from this example, the linear irregularities occurring at a specific cycle may be extracted by other fashions. A specific-cycle irregularity extracting section may convert the images L and R to frequency domain data by, for example, Fourier transform so as to extract linear irregularities occurring at a specific cycle using frequency domain data.

The detection-target-irregularity extracting section (detection-target-irregularity extracting means) 14 extracts the linear irregularities meeting predetermined conditions from the linear irregularities, occurring at the specific cycle T, which have been extracted by the specific-cycle irregularity extracting section 13. Specifically, the detection-target-irregularity extracting section 14 extracts linear irregularities detected at the same positions in the two images L and R from those occurring at the specific cycle T. The linear irregularities detected at the same positions in the images L and R are caused by deviations in thickness of dots from a normal value and affect quality (details will be given later). The detection-target-irregularity extracting section 14 also has a function of index determining means calculating defectiveness values for the extracted linear irregularities.

The output section 8 outputs, among others, results of the inspection by the defect inspecting section 7 to inform the user of the inspection system 1. Specifically, the output section 8 has a display (not shown) to produce an image display. The section 8 displays, for example, the images L and R stored in the memory section 6 and images of the linear irregularities extracted by the detection-target-irregularity extracting section 14.

### Process Flow for Inspection System

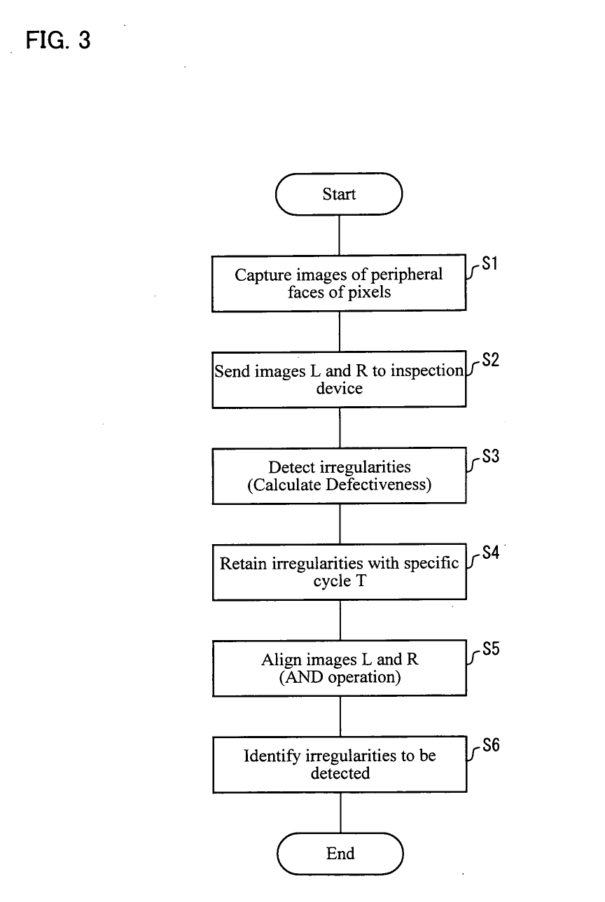

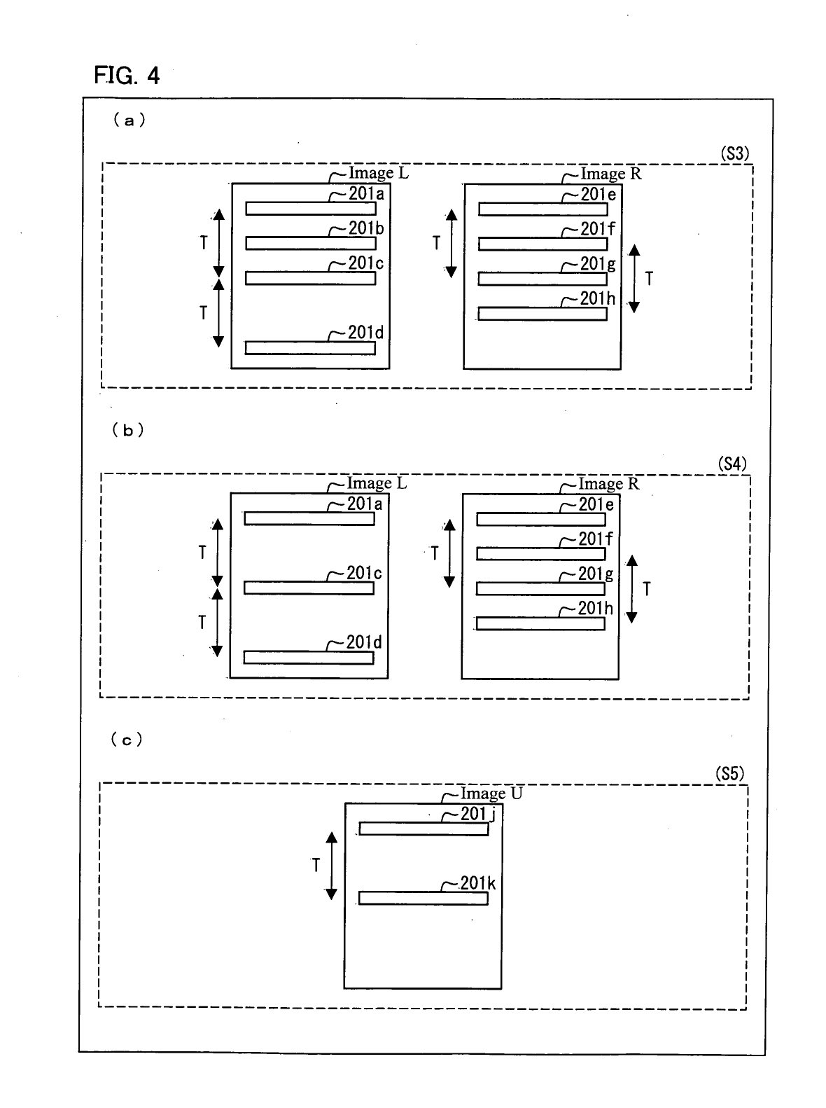

A process flow in the inspection system 1 configured as above will be described in reference to FIGS. 3 and 4. FIG. 3 is a flow chart illustrating an exemplary process executed by the inspection system 1. FIG. 4 is an illustration of an example of the process S3 to S5 in the flow chart of FIG. 3.

First, the imaging control section 5 in the inspection device 4 sends instructions to the imaging devices 2a and 2b to capture an image of the substrate P to be inspected (S1). In the example shown in FIG. 2, the imaging device 2a captures reflection from the peripheral face 103a, and the imaging device 2b captures reflection from the peripheral face 103b.

The imaging devices 2a and 2b sends the images of the substrate P, i.e. the images L and R, to the inspection device 4 so that the imaging control section 5 can record the images in the memory section 6 (S2). The present embodiment involves the imaging devices 2a and 2b to produce the images R and L; instead, a single imaging device may be moved to produce the images R and L.

As the images L and R are stored in the memory section 6, the image processing section 11 performs noise elimination on the images L and R. Accordingly, only linear irregularities are detected accurately in the inspection object.

Specifically, the image processing section 11 subjects the images L and R to Fourier transform, wavelet transform, or a like process for a conversion into frequency domain to remove frequency components from the frequency domain data, expect for a specific cycle T. Then, the section 1 1 subjects the data to Fourier inverse transform, wavelet inverse transform, or a like process for a back conversion to the images L and R in space domain. These procedures reject irregularities that are non-cyclic and that are cyclic, but not under consideration in the inspection. The modulation preferably rejects irregularities having cycles of T/2 or less. If the modulation rejects irregularities having cycles near T, the linear irregularities lose their features, making the detection less precise. T is the cycle at which specific-cycle linear irregularities occur.

Next, the linear irregularity detecting section 12 detects linear irregularities in each of the images L and R (S3). Specifically, the image processing section 11 detects, in each of the images L and R, regions where luminance is below a predetermined value as linear irregularities and obtains positions and defectiveness values for the detected linear irregularities. The linear irregularity detecting section 12 transmits data indicating the positions and defectiveness for the detected linear irregularities to the specific-cycle irregularity extracting section 13.

(a) of FIG. 4 illuminates exemplary linear irregularities detected in S3. As shown in the figure, four linear irregularities a to d are detected in the image L, and four linear irregularities e to h are detected in the image R. Still referring to the figure, the linear irregularities a and c have an interval of T, and the linear irregularities c and d have the same interval T, in the image L. In the image R, the linear irregularities e and g have an interval of T, and the linear irregularities f and h have the same interval T. All linear irregularities are detected in S3, no matter what cycle the linear irregularities have and no matter whether the linear irregularities are non-uniform deformation irregularities or not.

Next, the specific-cycle irregularity extracting section 13 having received the data indicating the positions and defectiveness for the linear irregularities, determines distances between the linear irregularities in each of the images L and R. The specific-cycle irregularity extracting section 13 then retains a group of linear irregularities having the specific cycle T as a candidate which could pose quality problems (S4). The specific-cycle irregularity extracting section 13 transmits data indicating the positions and defectiveness for the retained linear irregularities to the detection-target-irregularity extracting section 14.

All the linear irregularities having the cycle T are retained here, including those adjacent to two or more other linear irregularities at the cycle T (redundancy is allowed). The images L and R are processed independently and in parallel in S3 and S4.

(b) of FIG. 4 illuminates exemplary linear irregularities retained in S4. As shown in the figure, three linear irregularities a, c, d are retained in the image L, and four linear irregularities e to h are retained in the image R. Still referring to the figure, the linear irregularity b is not adjacent to any linear irregularities at the cycle T, hence rejected from the image L. The linear irregularities a and c are adjacent at the cycle T, hence retained. So are the linear irregularities c and d. Meanwhile, in the image R, the linear irregularities e and g have the interval T, and so do the linear irregularities f and h; these linear irregularities e to h are all retained.

The images L and R are both produced from the same substrate P. If the substrate P has linear irregularities at the cycle T, the linear irregularities appear at the same positions at the cycle T on the images L and R. Therefore, if there are linear irregularities retained at the same positions in the images L and R, the linear irregularities can be regarded as being those which need to be detected in the defect detection process. In contrast, if linear irregularities having the cycle T are detected in only the image L or R, the linear irregularities can be regarded as being non-uniform deformation irregularities which do not need to be detected in the defect detection process because those irregularities do not pose problems for the product quality of the substrate P.

For example, in the example in (b) of FIG. 4, the linear irregularities a and e are detected in both of the images L and R and can be regarded as being those which need to be detected in the defect detection process. The same discussion applies to the linear irregularities c and g. In contrast, the linear irregularities f and h are detected only in the image R: no linear irregularities are detected at the corresponding positions in the image L. The linear irregularities f and h can be therefore regarded as being non-uniform deformation irregularities.

Subsequently, having received the data indicating the positions and defectiveness for the linear irregularities from the specific-cycle irregularity extracting section 13, the detection-target-irregularity extracting section 14 aligns the images L and R (S5). Specifically, the detection-target-irregularity extracting section 14 performs an AND operation in accordance with the positions of the linear irregularities in image L and those in image R.

In other words, the detection-target-irregularity extracting section 14 retains only the linear irregularities that occur at the same positions in the images L and R. For example, if a linear irregularity is detected at position p in the image L, and a linear irregularity is detected at same position p in the image R, the detection-target-irregularity extracting section 14 retains the linear irregularity. On the other hand, the detection-target-irregularity extracting section 14 rejects linear irregularities that occur only in one of the images L and R.

The detection-target-irregularity extracting section 14 may align the images L and R by performing an AND operation on, for example, the frequency domain data representing the images L and R obtained by conversion in the image processing section 11.

(c) of FIG. 4 shows an exemplary linear irregularity retained in S5. The images L and R are consolidated to produce an image U as shown in the figure. The image U retains a linear irregularity i which corresponds to the linear irregularity a in the image L and the linear irregularity e in the image R and a linear irregularity j which corresponds to the linear irregularity c in the image L and the linear irregularity g in the image R. On the other hand, the linear irregularity d in the image L and the linear irregularities f and h in the image R are rejected.

S5 retains corresponding linear irregularities in the images L and R, that is, linear irregularities which appear at the same positions on the substrate P, as detailed above. Error could occur depending on the sizes and relative positions of imaging elements and dots. The corresponding linear irregularities in the images L and R do not need to be located at the exactly same positions in the images L and R. The detection-target-irregularity extracting section 14 is capable of detecting corresponding linear irregularities with various error ranges taken into account.

The detection-target-irregularity extracting section 14 concludes that the linear irregularities i and j retained in S5 have the specific cycle T and are caused by deviations of the (dot) thickness from a normal value, in other words, the target linear irregularities in the detection (S6), thereby terminating the process.

As described in the foregoing, the inspection system 1 of the present embodiment is capable of detecting only the linear irregularities which need to be detected in the defect detection process by extracting only the linear irregularities that have a specific cycle T from detected linear irregularities and further excluding non-uniform deformation irregularities from the extracted ones.

Even when linear irregularities develop due to deviations of dot thickness from a normal value, the irregularities do not pose quality problems for the substrate P as a product if the deviation of the dot thickness from the normal value, that is, the defectiveness, is low. Accordingly, the detection-target-irregularity extracting section 14 may compare the defectiveness of each linear irregularity retained in S6 against a predetermined inspection threshold, to determine whether the linear irregularity is problematic or acceptable. By so doing, the section 14 can reject the linear irregularities which have a low defectiveness value and pose no product quality problem and detect only the linear irregularities which have a high defectiveness value and pose product quality problem for the substrate P.

### Method of Detecting Non-Uniform Deformation Irregularities

Non-uniform deformation irregularities pose no product quality problems for the substrate P. The occurrence of such irregularities however will likely indicate that the manufacturing process of the substrate P has some problems. Therefore, problems in the manufacturing process can be closely examined through the detection of non-uniform deformation irregularities.

To detect non-uniform deformation irregularities, the detection-target-irregularity extracting section 14, when aligning the images in S5 in FIG. 3, only needs to reject linear irregularities detected at the same positions in the images L and R and retain the linear irregularities detected only in any one of the images L and R. Hence, only non-uniform deformation irregularities can be detected. Furthermore, the section 14 may calculate defectiveness for the detected non-uniform deformation irregularities to compare the defectiveness with a predetermined inspection threshold so as to detect only non-uniform deformation irregularities with high defectiveness values.

### Use of Inspection Results

As mentioned earlier, the substrate P is assumed here to be a color filter substrate colored by inkjet technology. A color filter substrate is manufactured through steps of forming a black matrix on a transparent substrate and of coloring among others as part of a manufacturing process of a color filter. The inspection system 1 inspects the color filter substrate to see whether the substrate is acceptable or defective, or in other words, whether the substrate has developed linear irregularities at a specific cycle. If the color filter substrate is determined to have no quality problems after completion of the inspection for linear irregularities, the substrate is subjected to predetermined processing to complete the manufacture of a color filter. In the current color filter manufacturing process, the steps prior to the inspection for linear irregularities are termed pre-processing, and the post-inspection steps are termed post-processing.

If the color filter substrate is determined by the inspection system 1 to have no quality problems, it is subjected to predetermined processing in the post-processing. On the other hand, if the color filter substrate is determined by the inspection system 1 to have problems, it is removed from the color filter manufacturing line and subjected to no post-processing. As can be seen here, the results of the inspection by the inspection system 1 are used in the color filter manufacturing process to determine after the inspection for linear irregularities whether to subject the color filter substrate to post-processing.

Some of the color filter substrate determined to be problematic may be repairable depending on the seriousness of the linear irregularities. Those which will be repaired and those which will be ultimately discarded may be picked up for separation in the post-processing, based on the defectiveness values of the detected linear irregularities determined by the inspection system 1.

For example, a threshold may be given in advance. A color filter substrate is discarded if it has developed linear irregularities with a defectiveness value equal to or exceeding the threshold. If linear irregularities are detected on a color filter substrate with a defectiveness value below the threshold, the substrate is repaired and inspected again by the inspection system 1.

The arrangement automatically removes color filter substrates which have developed serious defects that are difficult to repair and avoid wasting repairable color filter substrates.

Many linear irregularities occurring at a specific cycle are due to a cause in the manufacturing process as mentioned earlier. Manufacturing conditions can be hence adjusted to reduce linear irregularities occurring at specific cycles by feeding the results of the inspection by the inspection system 1 back to the pre-processing.

For example, if linear irregularities are detected and from the cycle, expected to be attributable to ink ejection, the quantity of ink ejection, the speed of the head unit, etc. may be adjusted/changed. If the linear irregularities are expected to be attributable to an unsuitable width of the black matrix, the position of the photo mask in the formation of the black matrix or another black matrix formation condition may be adjusted/changed.

The feedback adjusts/changes the manufacturing process according to the cycle of the detected linear irregularities, making it possible to efficiently manufacture color filter substrates with no linear irregularities by automatically modifying the manufacturing process for the color filter substrates.

### Embodiment 2

The preceding embodiment gave an example of detecting linear irregularities from a single image L and another single image R. The present embodiment will discuss an example in which, the images L and R are divided into corresponding regions so as to detect linear irregularities in each region. The division of the images L and R into regions improves precision in the detection of linear irregularities. Here, for convenience, members of the present embodiment that have the same arrangement and function as members of the preceding embodiment, and that are mentioned in that embodiment are indicated by the same reference numerals and description thereof is omitted.

An inspection system 1 of the present embodiment has the same configuration as in the preceding embodiment, except that the inspection device 4 has an image dividing section (image dividing means). Linear irregularities detection is performed by the same process as the one shown in FIG. 3. Accordingly, the following description will focus first on the image dividing section in the inspection device 4 and then on a specific data flow in the inspection system 1 of the present embodiment.

The image dividing section divides each of the images L and R of the substrate P, captured and stored in the memory section 6, into a plurality of images and outputs the divided images to the defect inspecting section 7. Specifically, the image dividing section divides the images L and R into corresponding regions. In other words, the image dividing section divides the images L and R so that the images obtained by the division of the image L correspond respectively to the images obtained by the division of the image R (so that the corresponding images show the same regions of the substrate P). Note that errors could occur depending on the size and relative positions of imaging elements and dots. The images L and R do not need to be divided at exactly the same places: the images L and R are divided at the “same” places taking error margins into consideration.

The image dividing section is assumed here to divide the image L into four regions (images LA to LD) adjoining each other in the plotting direction and the image R into four regions (images RA to RD) adjoining each other in the plotting direction. Needless to say, these are not the only possible regions: the division may be set up in a suitable manner depending on various factors including the shape and size of the substrate P and the resolution of the imaging devices 2. Adjacent regions may overlap.

The defect inspecting section 7, in the preceding embodiment, inspected the presence of linear irregularities across the entire surface of the substrate P on the basis of the images L and R stored in the memory section 6. In the present embodiment, the section 7 inspects the presence of linear irregularities on the basis of the images LA to LD and the images RA to RD into which the images L and R are divided by the image dividing section. Therefore, in the present embodiment, the substrate P is divided into a plurality of regions, and each of the regions is inspected for the presence of linear irregularities.

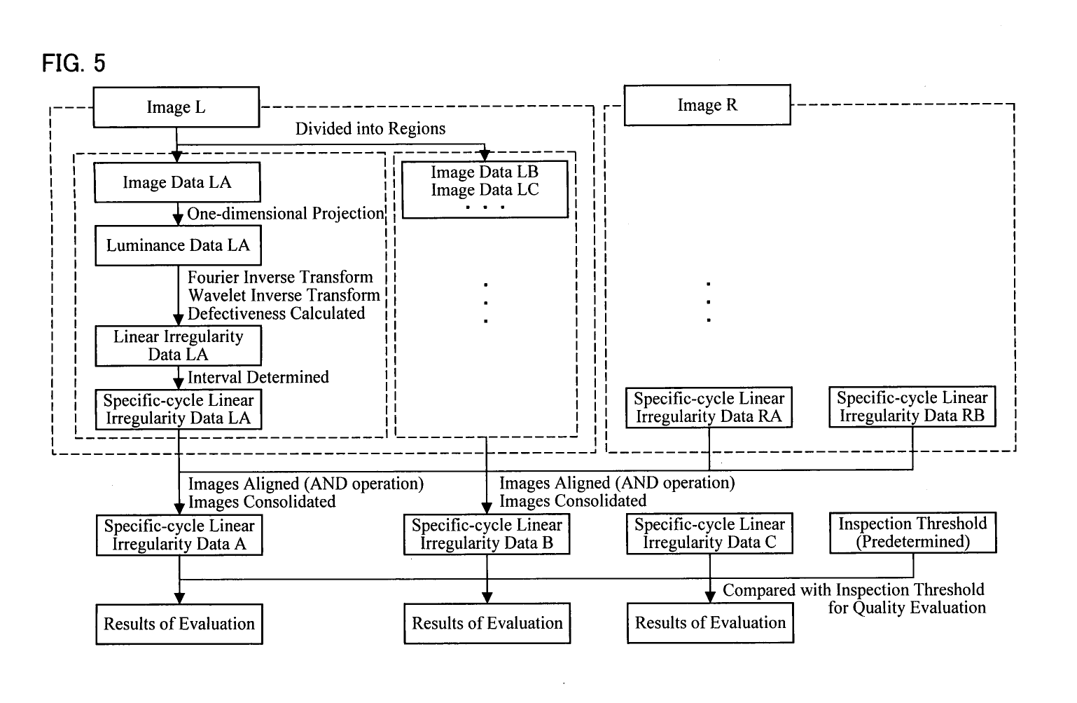

Next, a data flow in the inspection system 1 of the present embodiment will be described in reference to FIG. 5. FIG. 5 is an illustration of an exemplary data flow in the inspection system 1.

As the images L and R of the substrate P are stored in the memory section 6, the image dividing section divides the image L into four regions (images LA to LD) and the image R into four regions (images RA to RD). The images obtained by the division are transmitted sequentially to the image processing section 11. FIG. 5 primarily depicts the processing on the image data LA obtained by the division of the image L. Other sets of image data (image data LB to LD, RA to RD) are similarly processed.

Specifically, the image dividing section sends the images LA and RA, and then the images LB and RB, to the image processing section 11. Similarly, the image dividing section sends the images LC and RC, and then the images LD and RD. In other words, the image dividing section sends the images obtained by the division in sets of corresponding images (which show the same region of the substrate P by projecting light in different directions and capturing the reflections of the light off the region from different image capturing positions) to the image processing section 11.

Taking a given direction as a project direction the image processing section 11 performs one-dimensional projection processing on luminance distribute information contained in the images received from the image dividing section. In other words, the image processing section 11 adds up, and calculates an average of, luminance levels for each set of two-dimensional image data (images LA to LD and images RA to RD) in a direction parallel to linear irregularities (plotting direction) to generate one-dimensional luminance level data LA to LD and RA to RD. The one-dimensional projection processing may be of any kind so long as the processing can convert data from one dimension two dimensions. For example, the luminance levels may be integrated in a direction parallel to linear irregularities or summed with weights.

Subsequently, the image processing section 11 subjects the generated luminance level data LA to LD and RA to RD to Fourier transform, wavelet transform, or like publicly known technique for a conversion to frequency domain to remove noise components and subjects results to Fourier inverse transform, wavelet inverse transform, etc. to obtain space domain data. The range of frequencies at which noise is removed by inverse transform is preferably a range at which specific-cycle linear irregularities, or detection targets, are not modulated. The image processing section 11 transmits the luminance level data LA to LD and RA to RD after the noise removal sequentially to the linear irregularity detecting section 12.

The linear irregularity detecting section 12 detects linear irregularities in each set of the incoming luminance level data LA to LD and RA to RD and calculates defectiveness and position for each detected linear irregularity. In the following description, the data indicating the defectiveness and positions for the linear irregularities detected in the images LA to LD and RA to RA will be referred to as the linear irregularity data LA to LD and RA to RA.

The linear irregularity detecting section 12 transmits the linear irregularity data LA to LD and RA to RA obtained as above, sequentially to the specific-cycle irregularity extracting section 13. The specific-cycle irregularity extracting section 13 determines intervals between the incoming linear irregularity data LA to LD and RA to RA, retaining linear irregularities having a specific cycle while rejecting the other linear irregularities, to generate specific-cycle linear irregularity data LA to LD and RA to RA.

The specific-cycle irregularity extracting section 13 transmits the generated specific-cycle linear irregularity data LA to LD and RA to RA to the detection-target-irregularity extracting section 14 which in turn aligns combinations of corresponding specific-cycle linear irregularity data.

In other words, the detection-target-irregularity extracting section 14 performs an AND operation for each divided region to consolidate the specific-cycle linear irregularity data LA to LD generated from the image L and the specific-cycle linear irregularity data RA to RD generated from the image R. The data obtained by the consolidation will be referred to as the specific-cycle linear irregularity data A to D in the following description.

The data consolidation consolidates data not only in terms of the defect cycles, but also in terms of the defectiveness. In other words, the specific-cycle linear irregularity data A to D reflects the defectiveness of the linear irregularities in the specific-cycle linear irregularity data LA to LD and RA to RA.

The defectiveness of the specific-cycle linear irregularity data can be reflected for example by taking, as the consolidated defectiveness values for the linear irregularities, the arithmetic average of defectiveness values of the linear irregularities which are detected at corresponding positions in two images to be consolidated. Alternatively, the lower one of the defectiveness values of the linear irregularities which are detected at corresponding positions in two images to be consolidated may be taken as the post-consolidation defectiveness values.

The defectiveness of the linear irregularities may possibly affected by noise components in the image data. To avoid this, defectiveness values may be calculated for noise components in the frequency domain data produced by the conversion of the images L and R into frequency domain by the image processing section 11. Alternatively, the defectiveness value of the image containing noise components with lower defectiveness values may be taken as the defectiveness value for the post-consolidation image when the specific-cycle irregularity extracting section 13 performs the consolidation.

The image dividing section divides the images L and R respectively into the images LA to LD and RA to RD to generate the specific-cycle linear irregularity data A to D corresponding to the individual regions as above in the present embodiment.

The specific-cycle irregularity extracting section 13 evaluates if each set of specific-cycle linear irregularity data A to D is acceptable in view of a predetermined inspection threshold. The specific-cycle irregularity extracting section 13 transmits the specific-cycle linear irregularity data A to D except for linear irregularities with a defectiveness value below the inspection threshold as results of the evaluation to the output section 8. Accordingly, the output section 8 outputs the results of the evaluation corresponding to respective regions A to D.

### Consolidation of Evaluation Results

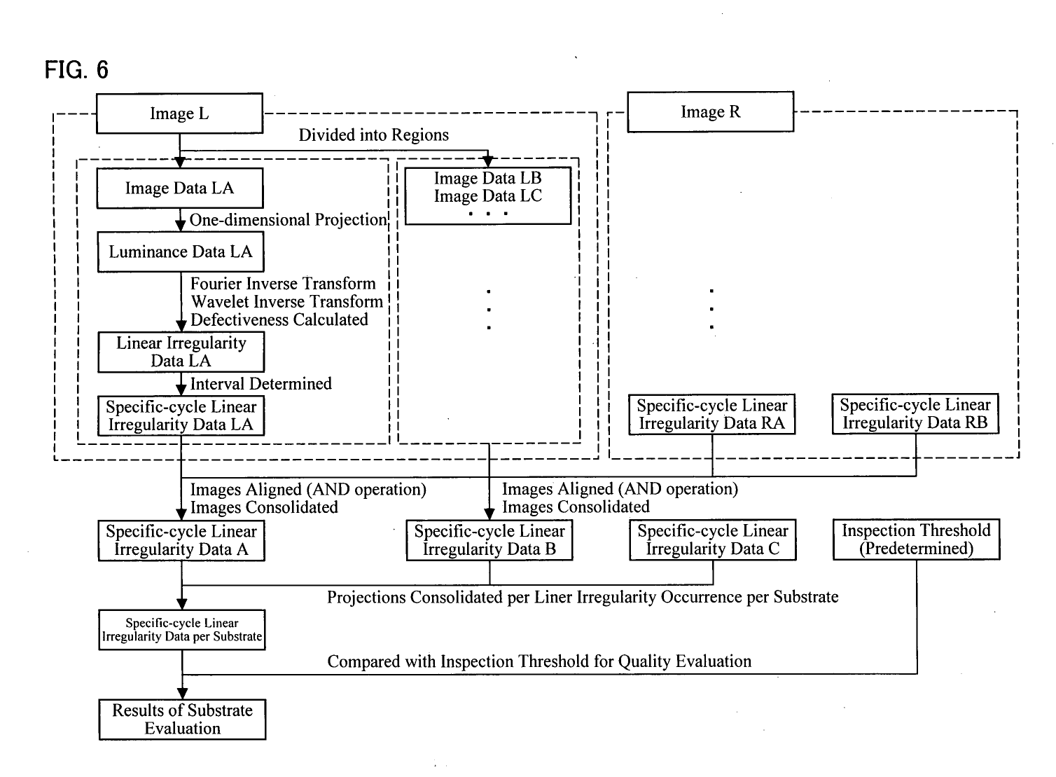

Results of the evaluation for each divided region were output in the example above. Referring to FIG. 6, the following will describe an example in which results of the evaluation are consolidated for each substrate or each group of substrates before being output. FIG. 6 is an illustration of an exemplary data flow in the inspection system 1. The process as in FIG. 5 is performed in FIG. 6 up to the generation of the specific-cycle linear irregularity data A to D. The description will focus on the process after the generation of the specific-cycle linear irregularity data A to D.

Having generated the specific-cycle linear irregularity data A to D, the detection-target-irregularity extracting section 14 consolidates the specific-cycle linear irregularity data A to D to generate specific-cycle linear irregularity data per substrate (consolidated linear irregularities for one substrate P being inspected). The inspection object irregularity extracting section 14 compares the defectiveness for the linear irregularities in the specific-cycle linear irregularity data per substrate with a predetermined inspection threshold to transmit the positions and defectiveness for the linear irregularities with a defectiveness value equal to or above the inspection threshold as results of the substrate evaluation to the output section 8. Hence, the output section 8 can output results of the evaluation covering the entire surface of the substrate P.

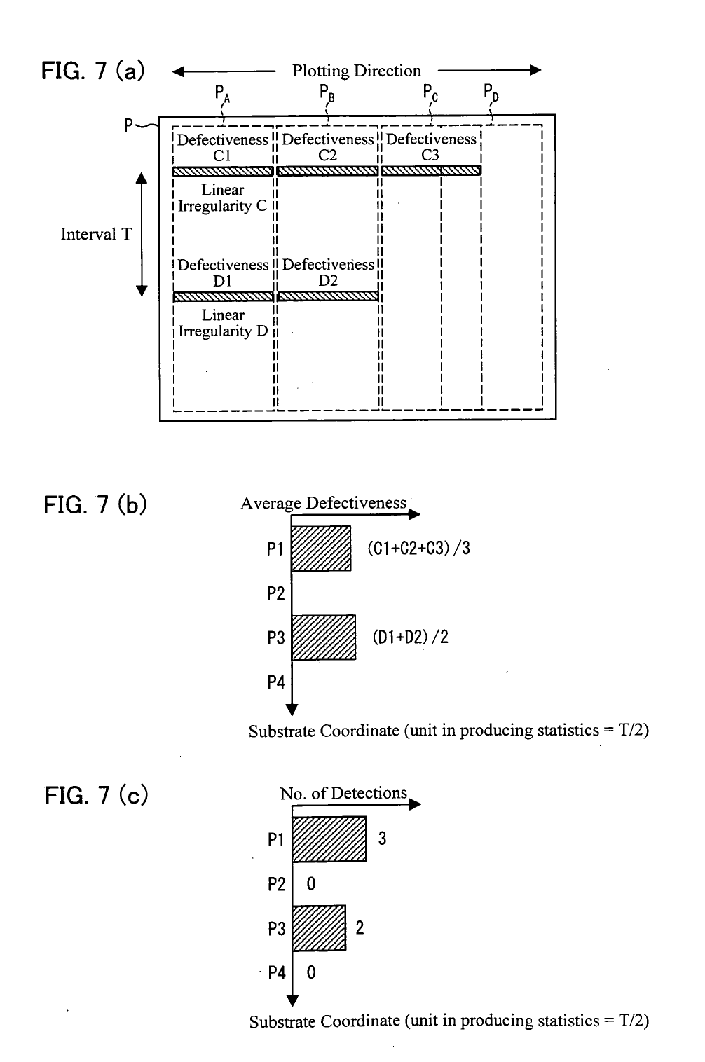

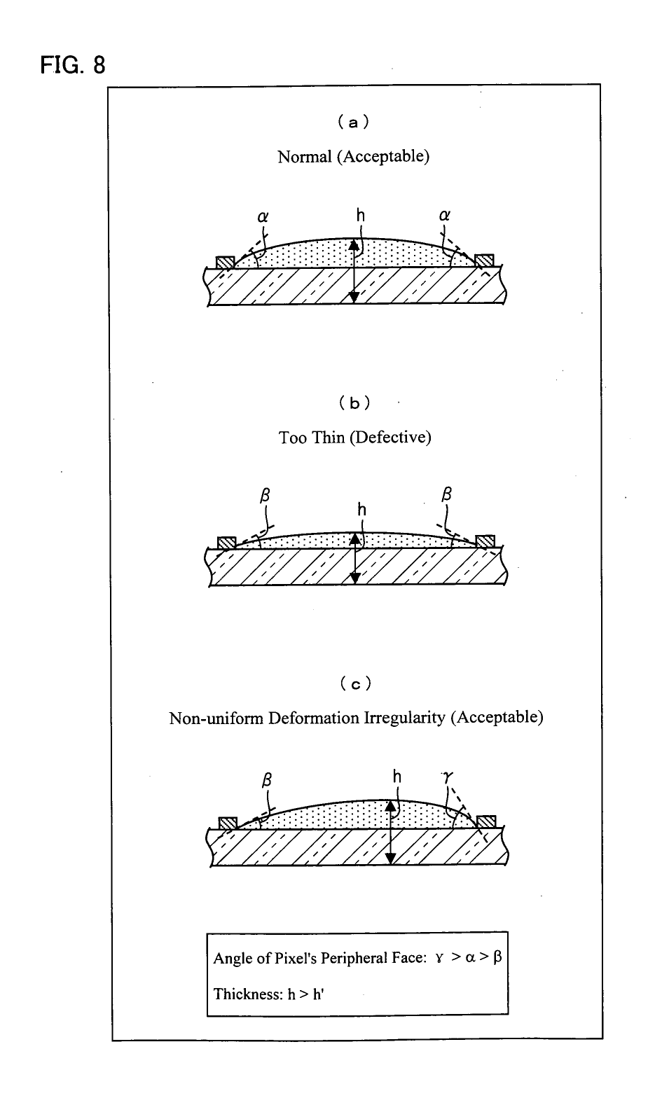

Now, a method of consolidating specific-cycle linear irregularity data across regions will be described in reference to FIG. 7(a) to (c). FIG. 7(a) is an illustration of an exemplary state of linear irregularities detected across multiple regions. The substrates P is assumed here to have been divided into four regions P_{A} to P_{D} which are adjacent to each other in the plotting direction as shown in the figure. The regions P_{C} and P_{D} is overlapping as shown in the figure. The region P_{A} corresponds to the images LA and RA, the region P_{B} to the images LB and RB, the region P_{C} to the images LC and RC, and the region P_{D} to the images LD and RD.

The linear irregularity C is separated from the linear irregularity D by a distance of T on the substrate P as shown in the figure. The substrate P is assumed to be colored by inkjet technology as mentioned earlier; many of the linear irregularities occurring at a specific cycle due to a cause in the manufacturing process develop parallel to the plotting direction. Consequently, the linear irregularity C extends across the three regions P_{A} to P_{C}. The parts of the linear irregularity in the regions represent a straight line parallel to the plotting direction.

C1 is the defectiveness of the part of the linear irregularity C in the region P_{A}. C2 is the defectiveness of the part of the linear irregularity C in the region P_{B}. C3 is the defectiveness of the part of the linear irregularity C in the region P_{C}. Likewise the linear irregularity D extends across the two regions P_{A} and P_{B}. The parts of the linear irregularity in the regions represent a straight line parallel to the plotting direction. D1 is the defectiveness of the part of the linear irregularity D in the region P_{A}. D2 is the defectiveness of the part of the linear irregularity D in the region P_{B}.

The detection-target-irregularity extracting section 14, after detecting specific-cycle linear irregularities in the regions P_{A} to P_{D}, consolidates the specific-cycle linear irregularities extending along the same straight line on the substrate P. The section 14 extracts the consolidated linear irregularities as consolidated linear irregularities (linear irregularities C and D). The detection-target-irregularity extracting section 14 then calculates a defectiveness value for each consolidated linear irregularity.

Specifically, the detection-target-irregularity extracting section 14 produces statistics of the defectiveness values in the plotting direction, taking the cycle at which linear irregularities occur as the unit in producing the statistics. For example, the arithmetic average of the defectiveness values is used, and the unit is set to half the cycle T. The defectiveness per substrate, that is, defectiveness value for each consolidated linear irregularity, is calculated from equation (1), considering the number of regions in which an irregularity is detected.

(Defectiveness per Substrate)=(Average Defectiveness)×(No. of Regions Containing Irregularity)/(Total No. of Regions) (1)

(Average Defectiveness)=(Sum of Defectiveness)/(No. of Regions Containing Irregularity) (2)

Average defectiveness values are determined for the linear irregularities C and D on the substrate P shown in FIG. 7(a) using equation (2). Results are shown in FIG. 7(b) which is an illustration of an exemplary relationship between a coordinate taken on the substrate P being inspected and average defectiveness values.

In the figure, positions in the direction perpendicular to the plotting direction on the substrate P are plotted on the vertical axis (substrate coordinate). The unit in producing the statistics here is T/2 as shown in the figure. In other words, P1 is separated from P2 by a distance of T/2 in the figure. So are P2 and P3 from P3 and P4 respectively. Average defectiveness values (average values of defectiveness) are plotted on the horizontal axis in the figure. Still referring to the figure, the linear irregularity C, detected at position P1, has an average defectiveness value (C1+C2+C3)/3. Similarly, the linear irregularity D, detected at position P3, has an average defectiveness value (D1+D2)/2.

FIG. 7(c) is an illustration of an exemplary relationship between a coordinate taken on the substrate P being inspected and a detection count indicating the number of regions in which a linear irregularity is detected. As shown in the figure, the detection count is 3 at position P1 and 2 at position P3. These figures indicate, as shown in FIG. 7(a), that the linear irregularity C at position P1 is detected in three of regions P_{A} to P_{D} and that the linear irregularity D at position P3 is detected in two of regions P_{A} to P_{D}.

The defectiveness per substrate of the linear irregularity C therefore is calculated by evaluating equation (1) using the numeric values given in FIGS. 7(b) and 7(c): {(C1+C2+C3)/3}×3/4=(C1+C2+C3)/4. Similarly, the defectiveness per substrate of the linear irregularity D is {(D1+D2)/2}×2/4=(D1+D2)/4.

A defectiveness (of a consolidated linear irregularity) per substrate calculated as above can be used as defectiveness per substrate which have taken into account the defectiveness of linear irregularities in each region and the occurrence and distribution of the linear irregularities. Therefore, the detection-target-irregularity extracting section 14 can determine, for each substrate, that is, for each consolidated linear irregularity, whether the irregularity is acceptable or defective, by comparing the defectiveness per substrate (of the consolidated linear irregularity) calculated by equation (1) with a predetermined inspection threshold.

If a plurality of substrates P manufactured under the same conditions are inspected for linear irregularities, it may be determined whether the irregularity is acceptable or defective, by consolidating the substrates P. Specifically, when that is the case, equation (3) below is used in place of equation (1). Equation (3) is an extrapolation for equation (1) to cover groups of substrates. The equations share the same basic concepts. The “Total No. of Regions” in equation (3) is the sum of the numbers of regions of all groups of substrates. Accordingly, In this configuration, it can be collectively determined whether each group of substrates is acceptable or defective, using a predetermined inspection threshold.

(Defectiveness for Group of Substrates)=(Average Defectiveness)×(Number of Regions Containing Irregularity)/(Total No. of Regions) (3)

The present invention is not limited to the description of the embodiments above, but may be altered by a skilled person within the scope of the claims. An embodiment based on a proper combination of technical means disclosed in different embodiments is encompassed in the technical scope of the present invention.

Finally, the blocks of the inspection device 4, especially, the imaging control section 5, the defect inspecting section 7, and the image dividing section, may be implemented by hardware or software executed by a CPU as follows:

The inspection device 4 includes a CPU (central processing unit) and memory devices (storage media). The CPU executes instructions contained in control programs, realizing various functions. The memory devices may be a ROM (read-only memory) which contains programs, a RAM (random access memory) to which the programs are loaded, or a memory containing the programs and various data. The objective of the present invention can be achieved also by mounting to the inspection device 4 a computer-readable storage medium containing control program code (executable programs, intermediate code programs, or source programs) for the inspection device 4 which is software realizing the aforementioned functions, in order for the computer (or CPU, MPU) to retrieve and execute the program code contained in the storage medium.

The storage medium may be, for example, a tape, such as a magnetic tape or a cassette tape; a magnetic disk, such as a floppy® disk or a hard disk, or an optical disc, such as CD-ROM/MO/MD/DVD/CD-R; a card, such as an IC card (memory card) or an optical card; or a semiconductor memory, such as a mask ROM/EPROM/EEPROM/flash ROM.

The inspection device 4 may be arranged to be connectable to a communications network so that the program code may be delivered over the communications network. The communications network is not limited in any particular manner, and may be, for example, the Internet, an intranet, extranet, LAN, ISDN, VAN, CATV communications network, virtual dedicated network (virtual private network), telephone line network, mobile communications network, or satellite communications network. The transfer medium which makes up the communications network is not limited in any particular manner, and may be, for example, a wired line, such as IEEE 1394, USB, an electric power line, a cable TV line, a telephone line, or an ADSL; or wireless, such as infrared (IrDA, remote control), Bluetooth®, 802.11 wireless, HDR, a mobile telephone network, a satellite line, or a terrestrial digital network. The present invention encompasses a carrier wave, or data signal transmission, by which the program code is embodied electronically.

As described in the foregoing, an inspection device of the present invention includes: linear irregularity detecting means for detecting linear irregularities individually in a first and a second image, the first image being produced of the surface mounds by projecting light from a first direction onto the inspection surface, the second image being produced of the surface mounds by projecting light from a second direction, which differs from the first direction with respect to the inspection surface; specific-cycle irregularity extracting means for extracting linear irregularities detected at predetermined intervals in the individual first and second images, the intervals being taken vertical to the linear irregularities on the inspection surface; and detection-target-irregularity extracting means for extracting a linear irregularity detected in both the first and second images as a detection-target linear irregularity.

An inspection system of the present invention includes: an illumination device for projecting light from a first and a second direction onto an inspection object; an imaging device for producing a first image of the inspection object being illuminated with the light projected by the illumination device from the first direction and producing a second image of the inspection object being illuminated with the light projected by the illumination device from the second direction; and the inspection device for inspecting the inspection object based on the first and second images produced by the imaging device.

The inspection device of the present invention further includes: an illumination device for projecting light from the first and the second direction onto the inspection object; and an imaging device for producing the first image of the inspection object being illuminated with the light projected by the illumination device from the first direction and producing the second image of the inspection object being illuminated with the light projected by the illumination device from the second direction, wherein the inspection device inspects the inspection object based on the first and second images produced by the imaging device.

An inspection method of the present invention includes the steps of: detecting linear irregularities individually in a first and a second image, the first image being produced of the surface mounds by projecting light from a first direction onto the inspection surface, the second image being produced of the surface mounds by projecting light from a second direction, which differs from the first direction with respect to the inspection surface; extracting linear irregularities detected at predetermined intervals in the individual first and second images, the intervals being taken vertical to the linear irregularities on the inspection surface; and extracting a linear irregularity detected in both the first and second images as a detection-target linear irregularity.

The method/device/system is capable of distinguishing, in the detection, between non-uniform deformation irregularities (defects regarded as being acceptable) and specific-cycle linear irregularities (defects regarded as being unacceptable) occurring from deviations in thickness from normal surface mounds due to a cause in the manufacturing process.

Another inspection device of the present invention detects linear irregularities occurring on an inspection object having a plurality of surface mounds on an inspection surface and also in that the device includes: linear irregularity detecting means for detecting linear irregularities individually in a first and a second image, the first image being produced of the surface mounds by projecting light from a first direction onto the inspection surface, the second image being produced of the surface mounds by projecting light from a second direction, which differs from the first direction, onto the inspection surface; specific-cycle irregularity extracting means for extracting linear irregularities detected at predetermined intervals in the individual first and second images, the intervals being taken vertical to the linear irregularities on the inspection surface; and detection-target-irregularity extracting means for extracting a linear irregularity other than those detected in both the first and second images as a detection-target linear irregularity.

According to the arrangement, the linear irregularities occurring at the same positions in the first and second images are excluded. The detection-target linear irregularities are therefore non-uniform deformation irregularities (defects regarded as being acceptable). In other words, according to the arrangement, non-uniform deformation irregularities are detected which do not directly affect the quality of the inspection object, but which are due to a cause in the manufacturing process.

In the inspection device containing an illumination device and an imaging device, the illumination device and the imaging device may be integrated to the inspection device or built separately from the inspection device.

The inspection device further preferably includes image dividing means for dividing the first and second images at identical positions into multiple regions, wherein the linear irregularity detecting means, the specific-cycle irregularity detecting means, and the detection-target-irregularity extracting means extract a detection-target linear irregularity in each of the regions of the first and second images having been subjected to the image dividing.

According to the arrangement, the first and second images are each divided into a plurality of regions. Linear irregularities are detected in smaller regions. Therefore, the precision of the detection of linear irregularities improves according to the arrangement.

The image dividing means preferably divides the first and second images so that adjoining regions partially overlap each other.

If the first and second images are divided into a plurality of regions, a single linear irregularity can be detected across multiple regions. In that case, a problem arises that the precision of the detection of the linear irregularity falls at a boundary of the regions.

To avoid this, regions partially overlap in the arrangement. The overlapping prevents the precision of the detection of the linear irregularity from falling at a boundary of regions.

The inspection device preferably further includes index determining means for obtaining first and second indices indicative of defectiveness of linear irregularities detected at positions where detection-target linear irregularities are detected respectively in the first and second images based on difference in the first and second images between luminance at positions where detection-target linear irregularities are detected and luminance at positions where no linear irregularities are detected to determine a third index indicative of defectiveness of the detection-target linear irregularities based on the obtained first and second indices.

According to the arrangement, a third index indicative of the defectiveness of the detection-target linear irregularities is determined. The first to third indices are obtained from the difference between the luminance at the positions where linear irregularities are detected and the luminance at the positions where no linear irregularities are detected. Therefore, the greater the first to third indices, the greater the discrepancy of the thickness of the surface mounds from the normal value and the more serious the defects.

In other words, the arrangement enables to determine how serious a problem the extracted detection-target linear irregularities could be. Accordingly, processing in accordance with the seriousness of the defects can be executed. For example, a detection-target linear irregularity with a third index less than or equal to a predetermined threshold may not be regarded as being defective.

The third index indicative of defectiveness of the detection-target linear irregularities may be determine from the first and second indices, for example, by taking an arithmetic average of the first index and the second index as the third index.

The calculation of the first and second indices can be affected by noise components contained in the first and second images; the obtained, real values may be different from the correct values of the first and second indices. Specifically, letting I₀ be the correct value of either the first or second index and δI a noise component, the real value I of the first or second index is given by I=I₀+δI.

Especially, when non-uniform deformation irregularities have occurred, typically δI>0. Therefore, the real values of the first and second indices are usually greater than the correct values of the first and second indices. Therefore, when non-uniform deformation irregularities exist, the first and second indices indicative of the defectiveness of linear irregularities are so exaggerated that linear irregularities with low defectiveness could be erroneously detected.

Accordingly, in these cases, either the first index or the second index which has a smaller value may be designated the third index. Thus, linear irregularities with low defectiveness are not detected by error.

The inspection device preferably includes: frequency domain data generating means for converting the first and second images to frequency domain; and index determining means for obtaining first and second indices indicative of defectiveness of linear irregularities detected at positions where detection-target linear irregularities are detected respectively in the first and second images based on difference in the first and second images between luminance at positions where detection-target linear irregularities are detected and luminance at positions where no linear irregularities are detected to determine, as a third index indicative of defectiveness of the detection-target linear irregularities, either one of the first and second indices obtained from an image which, in frequency domain, contains frequency components, other than those corresponding to the detection-target linear irregularities, which have less defectiveness.

According to the arrangement, the index obtained from an image which, in frequency domain, contains frequency components, other than those corresponding to the detection-target linear irregularities, which have less defectiveness is designated the third index indicative of the defectiveness of the detection-target linear irregularities.

The frequency components corresponding to detection-target linear irregularities can be identified from the cycle of the extracted linear irregularities because the inspection device extracts linear irregularities with a specific cycle. The frequency components, other than those corresponding to the detection-target linear irregularities, which are not used in the extraction of the detection-target linear irregularities can be treated as noise components. The defectiveness of noise components in an image (defectiveness of frequency components other than those corresponding to the detection-target linear irregularities) can be calculated from the number of noise components detected in the image, the defectiveness of each noise component, etc.

If the image has few noise components or low defectiveness for the noise components, the defectiveness of linear irregularities can be obtained relatively accurately. Therefore, according to the arrangement, it can be said that one of the first and second indices which more accurately reflects the defectiveness of linear irregularities on the inspection object is designated the third index.

The frequency domain data generating means may remove the noise components from the frequency domain data of the first and second images and converts the frequency domain data of the first and second images from which the noise components are removed back to space domain data. In that case, the linear irregularity detecting means, the specific-cycle irregularity extracting means, and the detection-target-irregularity extracting means execute the predetermined processing explained above, based on the first and second images from which the noise components are removed. Accordingly, the calculation is less affected by the noise components, and the detection-target linear irregularities can be precisely extracted. Fourier transform and wavelet transform may be used to generate frequency domain data. Fourier inverse transform and wavelet inverse transform may be used to generate space domain data.

Preferably, if in an image containing frequency components, other than those corresponding to the detection-target linear irregularities, which have less defectiveness, the frequency components, other than those corresponding to the detection-target linear irregularities, have less defectiveness than a predetermined value, the index determining means determines the index obtained from that image as the third index indicative of defectiveness of the detection-target linear irregularities.

If the defectiveness of frequency components other than those corresponding to the detection-target linear irregularities, that is, the defectiveness of noise components, is high in both sets of frequency domain data generated from the first and second images, it is difficult to obtain first and second indices accurately representing the degree of linear irregularities occurring on the inspection object.

According to the arrangement, the third index is determined only when the defectiveness of noise components is less than a predetermined value. In other words, according to the arrangement, the third index is never determined when the first and second indices are both likely to be inaccurate due to noise components. Accordingly, the third index has improved reliability.

The inspection device preferably further includes frequency domain data generating means for converting the first and second images to frequency domain, wherein the detection-target-irregularity extracting means performs an AND operation on data obtained by converting the first image to frequency domain and data obtained by converting the second image to frequency domain to extract a linear irregularity detected in both the first and second images.

According to the arrangement, the linear irregularity detected in the first and second images at the same position can be extracted by simple computation.

The detection-target-irregularity extracting means preferably connects detection-target linear irregularities detected across multiple regions along an identical straight line on the inspection surface and extracts a connected line as a single consolidated linear irregularity.

When the first and second images are divided into multiple regions, detection-target linear irregularities are detected for each region. Therefore, a linear irregularity which appears as a single linear irregularity in the first and second images may be detected in multiple regions.

The arrangement consolidates detection-target linear irregularities, detected for each region, which extend along an identical straight line. Thus, the device can handle, as a single consolidated linear irregularity, a detection-target linear irregularity captured as a single linear irregularity in the first and second images, but extracted as a plurality of detection-target linear irregularities due to the image dividing. In addition, the device restrains variations of luminance levels among the divided images, exhibiting an improved S/N ratio.

The inspection device further includes: index determining means for obtaining first and second indices indicative of defectiveness of linear irregularities detected at positions where detection-target linear irregularities are detected respectively in the regions of the first and second images based on difference in the regions between luminance at positions where detection-target linear irregularities are detected and luminance at positions where no linear irregularities are detected to determine a third index indicative of defectiveness of the detection-target linear irregularities for each of the regions based on the obtained first and second indices; and index determining means for determining, as a fourth index indicative of defectiveness of the consolidated linear irregularity, an arithmetic average of third indices for the detection-target linear irregularities detected along an identical straight line on the inspection surface.

According to the arrangement, a fourth index indicative of the defectiveness of the consolidated linear irregularity is determined. The consolidated linear irregularity can be evaluated using the fourth index. For example, the fourth index may be compared with a predetermined threshold to decide whether or not the consolidated linear irregularity should be treated as a defective.

The inspection object is preferably a color filter. If the invention is to be applied to a color filter as the inspection object, the surface mounds correspond to colored dots of the color filter, and the inspection surface corresponds to the colored surface of the color filter.

The color filter contains a black matrix formed on the surface of a transparent substrate and manufactured by coloring dots separated by the black matrix. The color filter can develop linear irregularities which are in many cases due to a problem in the manufacturing process including application of color to the dots and fabrication of the black matrix. Therefore, linear irregularities are likely to occur along a straight line parallel to the plotting direction for the color filter and in many cases, at a constant cycle.

The inspection device does not identify non-uniform deformation irregularities which should be regarded as being acceptable as being defective. The device is capable of detecting only the linear irregularities which occur at a specific cycle due to deviations in thickness of the color filter and seriously affect the product quality of the color filter.

A method of manufacturing a color filter of the present invention is characterized in that it is a method of manufacturing a color filter with a color filter manufacturing device and the method involves the inspection step of executing the inspection method, wherein only color filters on which no detection-target linear irregularities are detected in the inspection step are subjected to manufacturing steps executed by the color filter manufacturing device subsequent to the inspection step.

According to the arrangement, unfinished color filters manufactured by the color filter manufacturing device are inspected in the inspection step by the inspection method of the present invention. Only the color filters on which no detection-target linear irregularities are detected in the inspection step are subjected to manufacturing steps subsequent to the inspection step to finish the color filters.

The inspection method of the present invention is capable of detecting the linear irregularities which occur at a specific cycle due to the presence of dots having a. less-than-normal thickness and seriously affect the product quality of the color filter. Therefore, the method of manufacturing a color filter is capable of excluding only color filters on which the linear irregularities have occurred from the manufacturing steps.

Another method of manufacturing a color filter of the present invention is characterized in that it is a method of manufacturing a color filter with a color filter manufacturing device and the method involves the inspection step of executing the inspection method, wherein if a detection-target linear irregularity is extracted in the inspection step, linear irregularity information containing at least one of a position, a defectiveness value, and a direction of the extracted detection-target linear irregularity is sent to the color filter manufacturing device.

According to the arrangement, the results of the inspection performed in the inspection step is transferred to the color filter manufacturing device. That enables improvement of the manufacturing step which contains a cause for the occurrence of linear irregularities and adjustment of the device so that linear irregularities no longer occur.

The inspection device may be implemented on a computer, in which case, the present invention encompasses a control program (including a computer-readable storage medium containing the program) which causes the computer to operate as the individual means of the inspection device to realize the individual means on the computer.

The terms and expressions that have been employed in the foregoing specification are used as terms of description and not of limitation, and there is no intention, in the use of such terms and expressions, of excluding equivalents of the features shown and described or portions thereof, it being recognized that the scope of the invention is defined and limited only by the claims that follow.

The present invention is applicable to inspection of any object so long as the object develops cyclic irregularities on a light-transmitting or -reflecting surface.

What is claimed is:

1. An inspection device, comprising:
linear irregularity detecting means for detecting linear irregularities individually in a first and a second image, the first image being produced of a plurality of surface mounds on an inspection surface of an inspection object by projecting light from a first direction onto the inspection surface, the second image being produced of the surface mounds by projecting light from a second direction, which differs from the first direction, onto the inspection surface;
specific-cycle irregularity extracting means for extracting linear irregularities detected at predetermined intervals in the individual first and second images, the intervals being taken vertical to the linear irregularities on the inspection surface; and
detection-target-irregularity extracting means for extracting a linear irregularity detected in both the first and second images as a detection-target linear irregularity.

2. The inspection device of claim 1, further comprising image dividing means for dividing the first and second images at identical positions into multiple regions, wherein
the linear irregularity detecting means, the specific-cycle irregularity detecting means, and the detection-target-irregularity extracting means extract a detection-target linear irregularity in each of the regions of the first and second images having been subjected to the image dividing.

3. The inspection device of claim 2, wherein the image dividing means divides the first and second images so that adjoining regions partially overlap each other.

4. The inspection device of claim 1, further comprising index determining means for obtaining first and second indices indicative of defectiveness of linear irregularities detected at positions where detection-target linear irregularities are detected respectively in the first and second images based on difference in the first and second images between luminance at positions where detection-target linear irregularities are detected and luminance at positions where no linear irregularities are detected to determine a third index indicative of defectiveness of the detection-target linear irregularities based on the obtained first and second indices.

5. The inspection device of claim 1, further comprising:
frequency domain data generating means for converting the first and second images to frequency domain; and
index determining means for obtaining first and second indices indicative of defectiveness of linear irregularities detected at positions where detection-target linear irregularities are detected respectively in the first and second images based on difference in the first and second images between luminance at positions where detection-target linear irregularities are detected and luminance at positions where no linear irregularities are detected to determine, as a third index indicative of defectiveness of the detection-target linear irregularities, either one of the first and second indices obtained from an image which, in frequency domain, contains frequency components, other than those corresponding to the detection-target linear irregularities, which have less defectiveness.

6. The inspection device of claim 5, wherein if in an image containing frequency components, other than those corresponding to the detection-target linear irregularities, which have less defectiveness, the frequency components, other than those corresponding to the detection-target linear irregularities, have less defectiveness than a predetermined value, the index determining means determines the index obtained from that image as the third index indicative of defectiveness of the detection-target linear irregularities.

7. The inspection device of claim 1, further comprising frequency domain data generating means for converting the first and second images to frequency domain, wherein
the detection-target-irregularity extracting means performs an AND operation on data obtained by converting the first image to frequency domain and data obtained by converting the second image to frequency domain to extract a linear irregularity detected in both the first and second images.

8. The inspection device of claim 2, wherein the detection-target-irregularity extracting means connects detection-target linear irregularities detected across multiple regions along an identical straight line on the inspection surface and extracts a connected line as a single consolidated linear irregularity.

9. The inspection device of claim 8, further comprising:
index determining means for obtaining first and second indices indicative of defectiveness of linear irregularities detected at positions where detection-target linear irregularities are detected respectively in the regions of the first and second images based on difference in the regions between luminance at positions where detection-target linear irregularities are detected and luminance at positions where no linear irregularities are detected to determine a third index indicative of defectiveness of the detection-target linear irregularities for each of the regions based on the obtained first and second indices; and
index determining means for determining, as a fourth index indicative of defectiveness of the consolidated linear irregularity, an arithmetic average of third indices for the detection-target linear irregularities detected along an identical straight line on the inspection surface.

10. The inspection device of claim 1, wherein the inspection object is a color filter.

11. An inspection device, comprising:
linear irregularity detecting means for detecting linear irregularities individually in a first and a second image, the first image being produced of a plurality of surface mounds on an inspection surface of an inspection object by projecting light from a first direction onto the inspection surface, the second image being produced of the surface mounds by projecting light from a second direction, which differs from the first direction, onto the inspection surface;
specific-cycle irregularity extracting means for extracting linear irregularities detected at predetermined intervals in the individual first and second images, the intervals being taken vertical to the linear irregularities on the inspection surface; and
detection-target-irregularity extracting means for extracting a linear irregularity other than those detected in both the first and second images as a detection-target linear irregularity.

12. The inspection device of claim 1, further comprising:
an illumination device for projecting light from the first and the second direction onto the inspection object; and
an imaging device for producing the first image of the inspection object being illuminated with the light projected by the illumination device from the first direction and producing the second image of the inspection object being illuminated with the light projected by the illumination device from the second direction,
wherein the inspection device inspects the inspection object based on the first and second images produced by the imaging device.

13. An inspection method, comprising the steps of:
detecting linear irregularities individually in a first and a second image, the first image being produced of a plurality of surface mounds on an inspection surface of an inspection object by projecting light from a first direction onto the inspection surface, the second image being produced of the surface mounds by projecting light from a second direction, which differs from the first direction, onto the inspection surface;
extracting linear irregularities detected at predetermined intervals in the individual first and second images, the intervals being taken vertical to the linear irregularities on the inspection surface; and
extracting a linear irregularity detected in both the first and second images as a detection-target linear irregularity.

14. A method of manufacturing a color filter, comprising the inspection step of executing the inspection method of claim 13 in a step of manufacturing a color filter by a color filter manufacturing device, wherein:
only color filters on which no detection-target linear irregularities are detected in the inspection step are subjected to manufacturing steps executed by the color filter manufacturing device subsequent to the inspection step; or
if a detection-target linear irregularity is extracted in the inspection step, linear irregularity information containing at least one of a position, a defectiveness value, and a direction of the extracted detection-target linear irregularity is sent to the color filter manufacturing device.

15. A computer-readable storage medium containing an inspection program causing a computer to operate as the individual means of the inspection device of claim 1.
